(19) United States
(12) Patent Application Publication
(10) Pub. No.: US 2019/0200465 A1
(43) Pub. Date: Jun. 27, 2019

(54) MULTILAYER WIRING BOARD

(71) Applicant: Ibiden Co., Ltd., Ogaki (JP)

(72) Inventors: Yoji Mori, Ogaki (JP); Toshihide Makino, Ogaki (JP); Taichi Ito, Ogaki (JP)

(73) Assignee: Ibiden Co., Ltd., Ogaki (JP)

(21) Appl. No.: 16/233,304

(22) Filed: Dec. 27, 2018

(30) Foreign Application Priority Data
Dec. 27, 2017 (JP) 2017-252427

(51) Int. Cl. H05K 3/46; H05K 1/11

(52) U.S. Cl. CPC H05K 3/4655; H05K 3/4661; H05K 3/4608; H05K 1/115

(57) ABSTRACT

A multilayer wiring board includes a base substrate including conductor layers and insulating layers formed such that the conductor layers and the insulating layers are laminated alternately and that the conductor layers include a first conductor pattern, an inter-pattern insulating resin layer formed on a surface of the base substrate and including an insulating resin layer and an insulating base material laminated on the insulating resin layer such that resin forming the insulating resin layer is filling gaps formed between portions of the first conductor pattern, and a second conductor pattern formed on an outer layer side of the first conductor pattern such that the inter-pattern insulating resin layer is formed between the first conductor pattern and the second conductor pattern. The base substrate, the inter-pattern insulating resin layer and the second conductor pattern form an antenna portion.

### CROSS-REFERENCE TO RELATED APPLICATIONS

The present application is based upon and claims the benefit of priority to Japanese Patent Application No. 2017-252427, filed Dec. 27, 2017, the entire contents of which are incorporated herein by reference.

### BACKGROUND OF THE INVENTION

### Field of the Invention

The present invention relates to a multilayer wiring board having asymmetrical structures on a front side and a back side thereof.

### Description of Background Art

Japanese Patent Laid-Open Publication No. 2010-10183 describes a multilayer wiring board having an asymmetrical structure. The entire contents of this publication are incorporated herein by reference.

### SUMMARY OF THE INVENTION

According to one aspect of the present invention, a multilayer wiring board includes a base substrate including conductor layers and insulating layers formed such that the conductor layers and the insulating layers are laminated alternately and that the conductor layers include a first conductor pattern, an inter-pattern insulating resin layer formed on a surface of the base substrate and including an insulating resin layer and an insulating base material laminated on the insulating resin layer such that resin forming the insulating resin layer is filling gaps formed between portions of the first conductor pattern, and a second conductor pattern formed on an outer layer side of the first conductor pattern such that the inter-pattern insulating resin layer is formed between the first conductor pattern and the second conductor pattern. The base substrate, the inter-pattern insulating resin layer and the second conductor pattern form an antenna portion.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a wiring board according to a first embodiment of the present invention;

FIG. 2A is a cross-sectional view of a first substrate;

FIG. 2B is a cross-sectional view of a second substrate;

FIG. 3A-3C are cross-sectional views illustrating manufacturing processes of the first substrate;

FIG. 4A-4C are cross-sectional views illustrating manufacturing processes of the first substrate;

FIG. 5A-5C are cross-sectional views illustrating manufacturing processes of the first substrate;

FIGS. 6A and 6B are cross-sectional views illustrating manufacturing processes of the first substrate;

FIG. 7A-7C are cross-sectional views illustrating manufacturing processes of the second substrate;

FIGS. 8A and 8B are cross-sectional views illustrating manufacturing processes of the wiring board;

FIGS. 9A and 9B are cross-sectional views illustrating manufacturing processes of the wiring board;

FIG. 10 is a cross-sectional side view of a multilayer wiring board according to a second embodiment;

FIG. 11A-11C are cross-sectional views illustrating manufacturing processes of a second substrate; and

FIGS. 12A and 12B are cross-sectional views illustrating manufacturing processes of the wiring board.

### DETAILED DESCRIPTION OF THE EMBODIMENTS

Embodiments will now be described with reference to the accompanying drawings, wherein like reference numerals designate corresponding or identical elements throughout the various drawings.

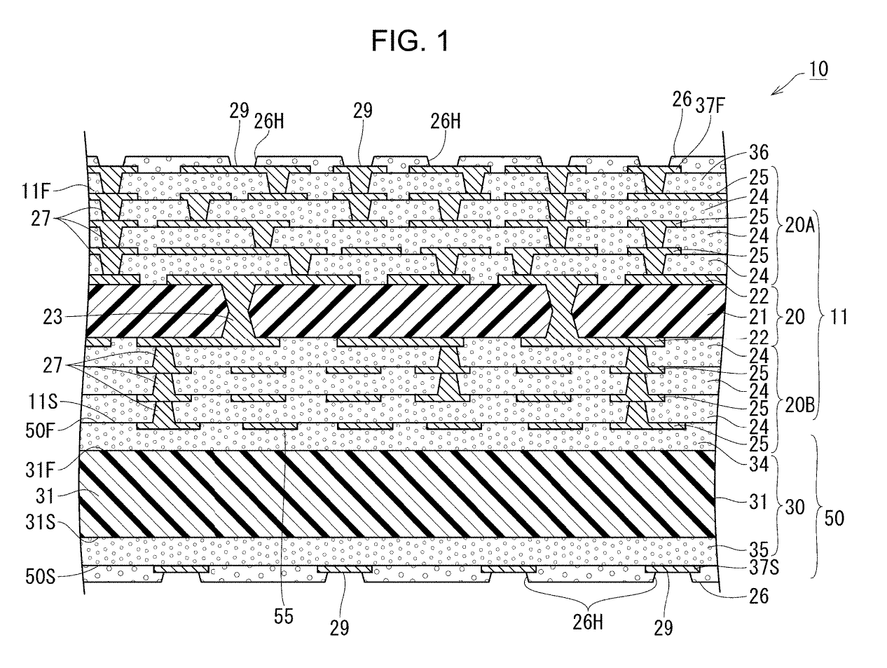

In the following, the present embodiment is described with reference to FIG. 1-9B. As illustrated in FIG. 1, a wiring board 10 of the present embodiment has a base substrate 11. An interlayer insulating resin layer 36 and a second conductor layer (37F) are laminated on an F surface (11F) which is a front side surface of the base substrate 11, and an inter-pattern insulating resin layer 30 and a second conductor layer (37S) are laminated on an S surface (11S) which is a back side surface of the base substrate 11.

The base substrate 11 includes a core substrate 20 which is formed from a first insulating base material 21 and conductor layers 22 respectively laminated on front and back sides of the first insulating base material 21, and build-up parts (20A, 20B) which are respectively laminated on front and back sides of the core substrate 20. In the first insulating base material 21, through-hole conductors 23 connecting to each other the conductor layer 22 on the front side and the conductor layer 22 on the back side are formed. In each of the build-up parts (20A, 20B), multiple interlayer insulating layers 24 and multiple conductor layers 25 are alternately laminated. In each of the interlayer insulating layers 24, via conductors 27 are formed. The first insulating base material 21 and the interlayer insulating layers 24 are each formed by impregnating a woven fabric of reinforcing fibers (for example, a glass cloth) with a resin. The first insulating base material 21 has a thickness of, for example, about 50-150 μm. Further, the interlayer insulating layers 24 each have a thickness of, for example, about 15-30 μm. The conductor layers (22, 25) are each formed mainly of a copper foil, an electroless copper plating, and an electrolytic copper plating, and each have a thickness of, for example, about 15-20 μm. The core substrate 20 has a thickness of, for example, about 80-190 μm.

In the interlayer insulating resin layer 36, via conductors 27 are formed. Then, due to the via conductors 27, the second conductor layer (37F), and a conductor layer 25 which is an outermost conductor layer on the F surface (11F) side among the conductor layers 25 of the base substrate 11 are connected to each other. The interlayer insulating resin layer 36 is formed by impregnating a woven fabric of reinforcing fibers (for example, a glass cloth) with a resin. Further, a thickness of the interlayer insulating resin layer 36 is substantially the same as that of each of the interlayer insulating layers 24, and is, for example, about 15-30 μm. The conductor layers (37F, 37S) are each formed mainly of a copper foil, an electroless copper plating, and an electrolytic copper plating, and each have a thickness of, for example, about 15-20 μm. The copper foil included in each of the conductor layers (22, 25, 37F, 37S) has a thickness of about 1-5 μm.

Then, an antenna part 50 is formed from the inter-pattern insulating resin layer 30, a first conductor layer 55 which is an outermost conductor layer 25 on the S surface (11S) side among the multiple conductor layers 25 of the base substrate 11, and the second conductor layer (37S). In this structure, the first conductor layer 55 and the second conductor layer (37S) are not electrically connected to each other.

Here, in the wiring board 10 of the present embodiment, the inter-pattern insulating resin layer 30 is formed from a second insulating base material 31, a first insulating resin layer 34 formed on an F surface (31F) side of the second insulating base material 31, and a second insulating resin layer 35 formed on an S surface (31S) side of the second insulating base material 31. The second insulating base material 31, the first insulating resin layer 34 and the second insulating resin layer 35 are each formed by impregnating a woven fabric of reinforcing fibers (for example, a glass cloth) with a resin. Thicknesses of the first insulating resin layer 34 and the second insulating resin layer 35 are each substantially the same as that of each of the interlayer insulating layers 24, and are each, for example, about 15-30 μm. The second insulating base material 31 has a thickness of, for example, about 200-300 μm.

In the wiring board 10 of the present embodiment, the thickness of the second insulating base material 31 is larger than the thickness of any one of the interlayer insulating layers 24 and the first insulating base material 21 of the base substrate 11. Further, the thickness of the second insulating base material 31 is 3 or more times the thickness of each of the interlayer insulating layers (24, 36), the first insulating resin layer 34 and the second insulating resin layer 35. Further, the thickness of the second insulating base material 31 is larger than the thickness of the core substrate 20. However, the thickness of the second insulating base material 31 may be smaller than or the same as the thickness of the core substrate 20.

Further, the entire F surface (31F) and S surface (31S) of the second insulating base material 31 are rough surfaces. That is, all surfaces of the second insulating base material 31 that are respectively bonded to the first insulating resin layer 34 and the second insulating resin layer 35 are rough surfaces. Roughness of each of the F surface (31F) and the S surface (31S) of the second insulating base material 31 is larger than 0.1-1.0 μm.

As illustrated in FIG. 1, solder resist layers 26 are respectively laminated on the second conductor layers (37F, 37S). In the solder resist layers 26, openings (26H) exposing portions of the second conductor layers (37F, 37S) are formed. Then, pads 29 are respectively formed in the portions of the second conductor layers (37F, 37S) exposed from the openings (26H). The solder resist layers 26 are each a resin layer that does not contain reinforcing fibers and each have a thickness of, for example, about 10-20 μm.

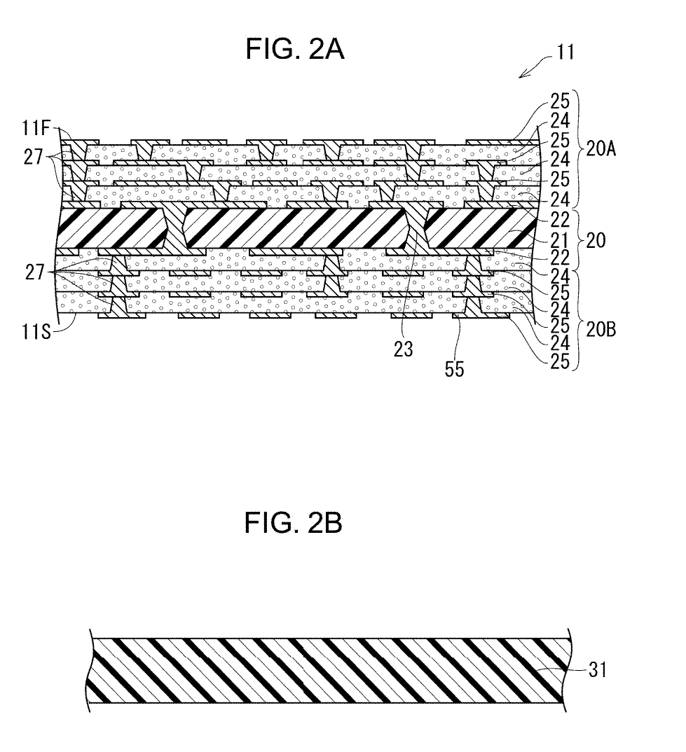

To manufacture the wiring board 10, first, the base substrate 11 (see FIG. 2A) and the second insulating base material 31 (see FIG. 2B) are prepared. In the following, a method for manufacturing the base substrate 11 and a method for manufacturing the second insulating base material 31 are described.

### Method for Manufacturing Base Substrate

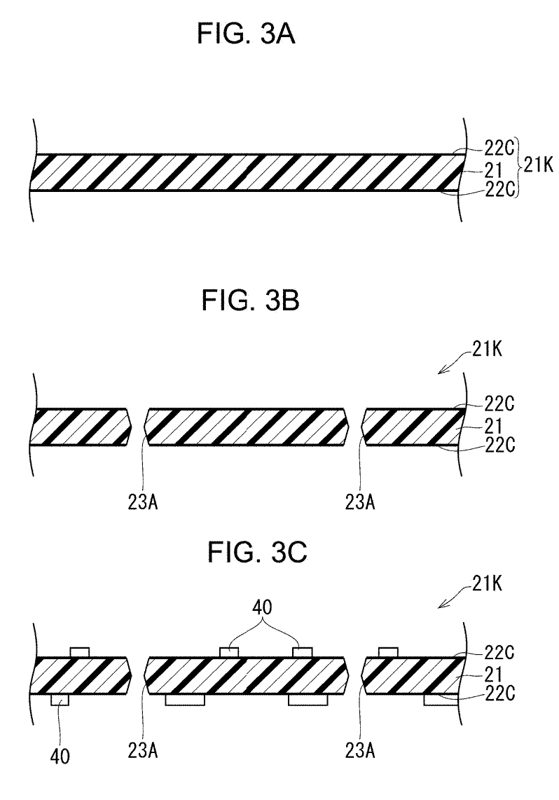

(A1) A copper-clad laminated plate (21K) illustrated in FIG. 3A is prepared. The copper-clad laminated plate (21K) is formed by laminating a copper foil (22C) on the front and back sides of the first insulating base material 21.

(A2) Through holes (23A) penetrating the copper-clad laminated plate (21K) are formed by subjecting the front and back sides of the copper-clad laminated plate (21K) to laser processing (see FIG. 3B). The through holes (23A) are each formed to have a shape that is reduced in diameter at a central portion in a thickness direction of the first insulating base material 21.

(A3) An electroless plating treatment is performed. An electroless plating film (not illustrated in the drawings) is formed on the copper foil (22C) and on inner surfaces of the through holes (23A). Next, a plating resist 40 of a predetermined pattern is formed on the electroless plating film on the copper foil (22C) (see FIG. 3C).

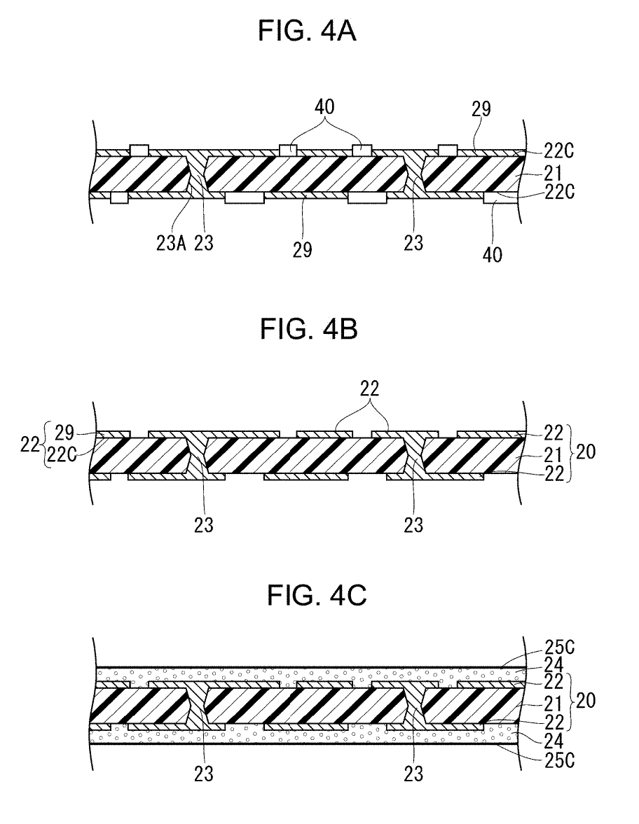

(A4) An electrolytic plating treatment is performed. The through-hole conductors 23 are formed by filling the through holes (23A) with electrolytic plating, and an electrolytic plating film 29 is formed in a non-forming portion of the plating resist 40 on the electroless plating film (not illustrated in the drawings) on the copper foil (22C) (see FIG. 4A).

(A5) The plating resist 40 is removed, and the electroless plating film (not illustrated in the drawings) and the copper foil (22C) under the plating resist 40 are removed. Then, the conductor layers 22 are respectively formed on the front and back sides of the first insulating base material 21 by the remaining electrolytic plating film 29, electroless plating film and copper foil (22C), and the front side conductor layer 22 and the back side conductor layer 22 are connected to each other by the through-hole conductors 23 (see FIG. 4B). As a result, the core substrate 20 is obtained.

(A6) As illustrated in FIG. 4C, on each of the conductor layers 22 on the front and back sides of the first insulating base material 21, a prepreg (a B stage resin sheet formed by impregnating a woven fabric of reinforcing fibers with a resin containing an inorganic filler) as an interlayer insulating layer 24, and a copper foil (25C) are laminated, and the resulting substrate is hot-pressed. In this case, gaps between portions of the conductor layers (22, 22) on the front and back sides of the first insulating base material 21 are filled with the prepreg. As an interlayer insulating layer 24, instead of a prepreg, it is also possible that a resin film that does not contain a woven fabric of reinforcing fibers but contains an inorganic filler is used. In this case, without laminating the copper foil (25C), a conductor layer 25 can be directly formed on a surface of the resin film using a semi-additive method.

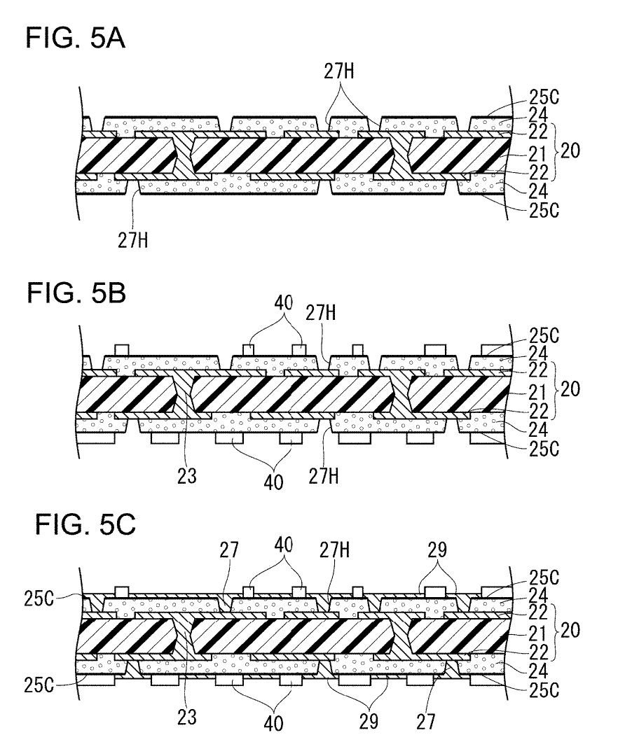

(A7) As illustrated in FIG. 5A, tapered via holes (27H) penetrating the copper foil (25C) and the interlayer insulating layer 24 are formed by irradiating CO2 laser to the copper foil (25C).

(A8) An electroless plating treatment is performed. An electroless plating film (not illustrated in the drawings) is formed on the copper foil (25C) and on inner surfaces of the via holes (27H). Next, a plating resist 40 of a predetermined pattern is formed on the electroless plating film (see FIG. 5B).

(A9) An electrolytic plating treatment is performed. As illustrated in FIG. 5C, the via conductors 27 are formed by filling the via holes (27H) with electrolytic plating, and an electrolytic plating film 29 is formed on portions of the electroless plating film (not illustrated in the drawings) exposed from the plating resist 40.

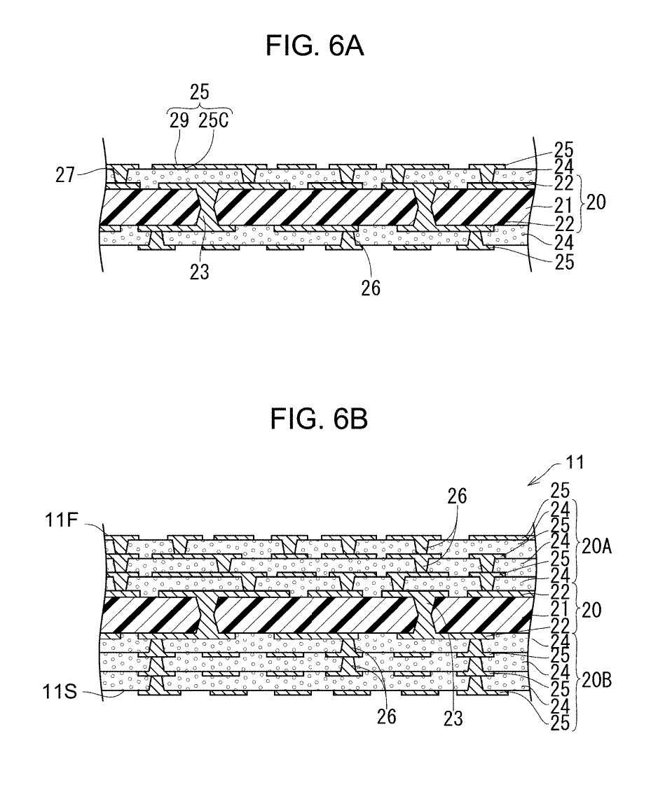

(A10) The plating resist 40 is removed, and the electroless plating film (not illustrated in the drawings) and the copper foil (25C) under the plating resist 40 are removed. Then, the conductor layers 25 are respectively formed on the interlayer insulating layers 24 by the remaining electrolytic plating film 29, electroless plating film and copper foil (25C) (see FIG. 6A). In this case, the conductor layers 25 are respectively connected to the conductor layers 22 by the via conductors 27.

(A11) By repeating the above-described processes of (A6)-(A10), as illustrated in FIG. 6B, the multiple interlayer insulating layers 24 and the multiple conductor layers 25 are alternately laminated on the conductor layers 22 of the first insulating base material 21, and the build-up parts (20A, 20B) are formed. In this case, conductor layers 25 adjacent to each other in a lamination direction are connected to each other by the via conductors 27 formed in the interlayer insulating layers 24. As a result, the base substrate 11 having the F surface (11F) on one side and the S surface (11S) on the other side is formed. The first conductor layer 55 is formed by the conductor layer 22 that forms an outermost layer on the S surface (11S) side of the base substrate 11.

### Method for Manufacturing Second Insulating Base Material

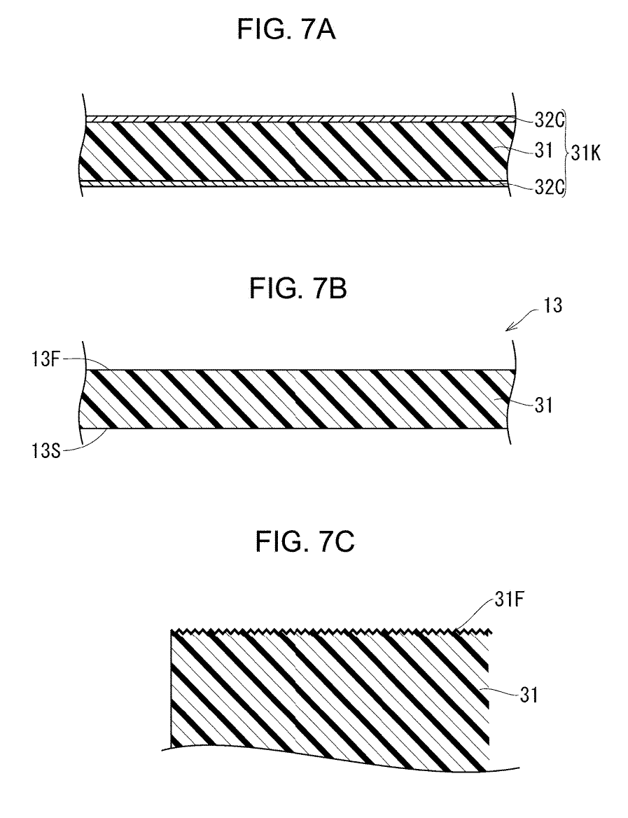

(B1) A copper-clad laminated plate (31K) illustrated in FIG. 7A is prepared. The copper-clad laminated plate (31K) is formed by laminating a copper foil (32C) on front and back sides of the second insulating base material 31.

(B2) An etching process is performed to remove the copper foil (32C) on the front and back sides of the copper-clad laminated plate (31K) (see FIG. 7B). As a result, the second insulating base material 31 illustrated in FIG. 7C in which the F surface (31F) and the S surface (31S) are rough surfaces is formed.

The descriptions about the methods for manufacturing the base substrate 11 and the second insulating base material 31 are as given above. Next, a method for manufacturing the wiring board 10 using the base substrate 11 and the second insulating base material 31 is described.

The wiring board 10 is manufactured as follows.

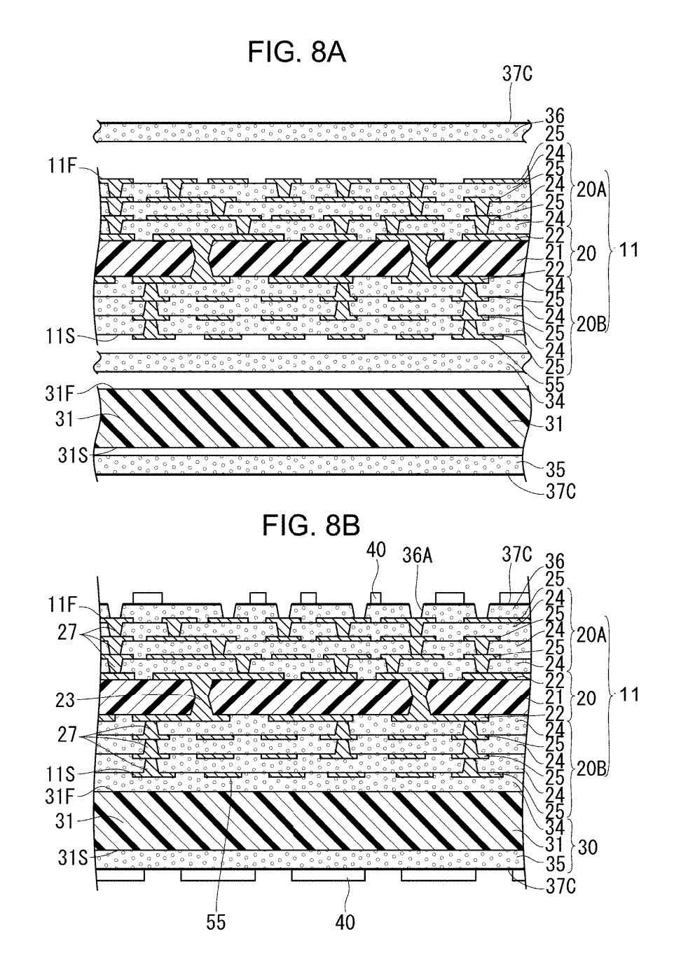

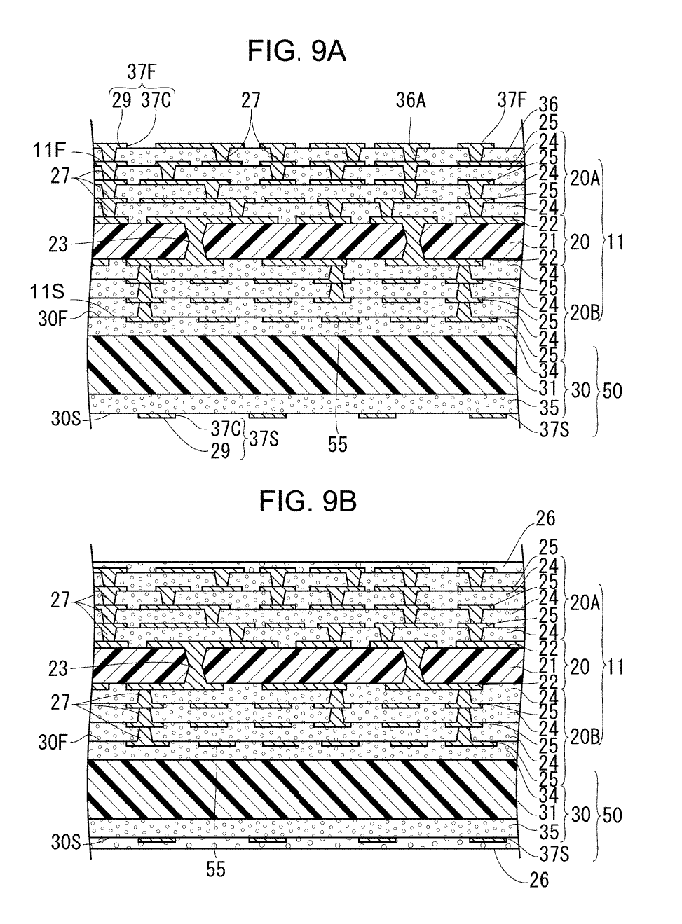

(1) As illustrated in FIG. 8A, in addition to the base substrate 11 and the second insulating base material 31, a prepreg as the first insulating resin layer 34, a prepreg as the second insulating resin layer 35, a prepreg as the interlayer insulating resin layer 36, and copper foils (37C, 37C) (see FIGS. 9A and 9B) are prepared. In an order from the F surface (11F), the copper foil (37C), the interlayer insulating resin layer 36, the base substrate 11, the first insulating resin layer 34, the second insulating base material 31, the second insulating resin layer 35, and the copper foil (37C) are sequentially laminated in this order, and the resulting substrate is hot-pressed. In this case, gaps between portions of the first conductor layer 55 are filled with the prepreg forming the first insulating resin layer 34. As each of the first insulating resin layer 34, the second insulating resin layer 35 and the interlayer insulating resin layer 36, instead of a prepreg, it is also possible that a resin film that does not contain a woven fabric of reinforcing fibers but contains an inorganic filler is used. In this case, without laminating the copper foils (37C), the conductor layers (37F, 37S) can each be directly formed on a surface of a resin film using a semi-additive method.

(2) Next, by irradiating CO2 laser to the copper foil (37C) on the F surface (11F) side, tapered via holes (36A) penetrating the copper foil (37C) and the interlayer insulating resin layer 36 are formed. An electroless plating treatment is performed. An electroless plating film (not illustrated in the drawings) is formed on the copper foil (37C) and on inner surfaces of the via holes (36A). Next, a plating resist 40 of a predetermined pattern is formed on the electroless plating film on the copper foil (37C) (see FIG. 8B).

(3) An electrolytic plating treatment is performed. The via conductors 27 are formed by filling the through holes (36A) with electrolytic plating, and an electrolytic plating film 29 is formed in a non-forming portion of the plating resist 40 on the electroless plating film (not illustrated in the drawings) on the copper foil (37C).

(4) The plating resist 40 is removed, and the electroless plating film (not illustrated in the drawings) and the copper foil (37C) under the plating resist 40 are removed. Then, the conductor layers (37F, 37S) are respectively formed on the interlayer insulating resin layer 36 and the second insulating resin layer 35 by the remaining electrolytic plating film 29, electroless plating film and copper foil (37C), and the conductor layer (37F) on the F surface (11F) side and the conductor layers 25 on the F surface (11F) side of the base substrate 11 are connected to each other by the via conductors 27 (see FIG. 9A).

(5) As illustrated in FIG. 9B, the solder resist layers (26, 26) are respectively laminated on the second conductor layers (37F, 37S). Next, a photoresist treatment is performed to form the openings (26H) in the solder resist layers (26, 26). Then, the pads 29 are respectively formed by the portions of the second conductor layers (37F, 37S) exposed from the openings (26H). As a result, the wiring board 10 illustrated in FIG. 1 is completed.

In the wiring board 10 of the present embodiment, the antenna part 50 includes the inter-pattern insulating resin layer 30, and the first conductor layer 25 and the second conductor layer (37S) that are respectively formed on the front and back sides of the inter-pattern insulating resin layer 30. Then, the inter-pattern insulating resin layer 30 has a structure that includes the second insulating base material 31 formed by removing the copper foils (32C, 32C) from the copper-clad laminated plate (31K). That is, the inter-pattern insulating resin layer 30 has the structure that includes the second insulating base material 31 that is already cured. Therefore, a thickness of the second insulating base material 31 can be easily increased. As a result, the wiring board 10 having asymmetrical structures on the front side and the back side can be easily manufactured.

Further, in the wiring board 10 of the present embodiment, when the second insulating base material 31 is formed sufficiently thick, that an electric signal transmitted in the base substrate 11 propagates as a noise to an electric signal transmitted in the second insulating base material 31 is suppressed.

Further, in the wiring board 10 of the present embodiment, the second conductor layer (37S) is formed after the second insulating base material 31 is laminated on the first insulating resin layer 34 filling the gaps between the portions of the first conductor layer 25. As a result, the second conductor layer (37S) can be formed on a flat surface, and thus, desired antenna characteristics can be easily obtained.

### Second Embodiment

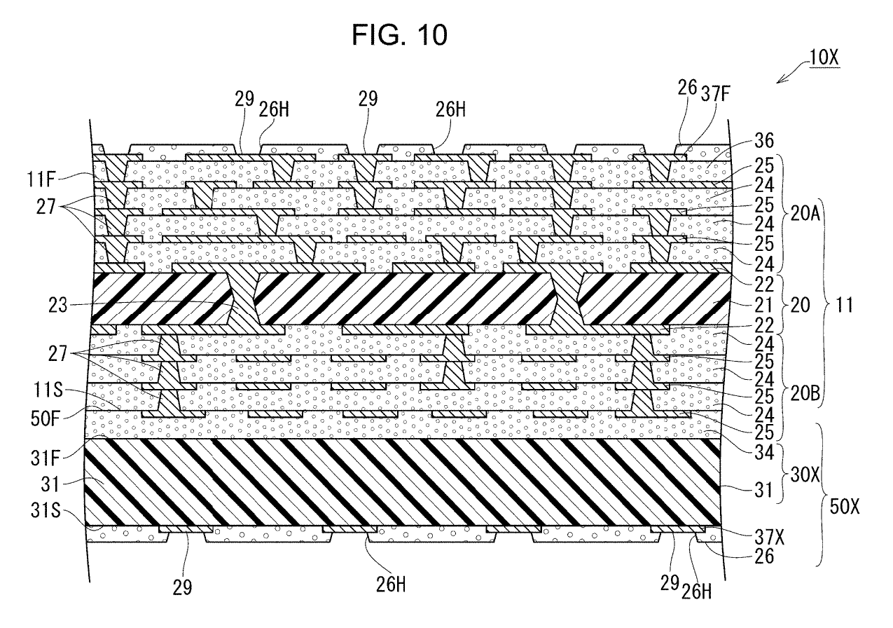

As illustrated in FIG. 10, a wiring board (10X) of a second embodiment is different from the wiring board 10 of the first embodiment in that the second insulating resin layer 35 laminated on the S surface (31S) of the second insulating base material 31 is not provided. Specifically, an inter-pattern insulating resin layer (30X) is formed from two layers including the second insulating base material 31 and the first insulating resin layer 34 laminated on the F surface (31F) of the second insulating base material 31. Then, a second conductor layer (37X) is laminated on the S surface (31S) of the second insulating base material 31. A metal foil included in each of the first conductor layers 25 of the present embodiment has a thickness of about 1-5 μm. A metal foil included in the second conductor layer (37X) has a thickness of 7-10 pun. In the following, a method for manufacturing the wiring board (10X) of the present embodiment is described mainly with respect to differences from the first embodiment.

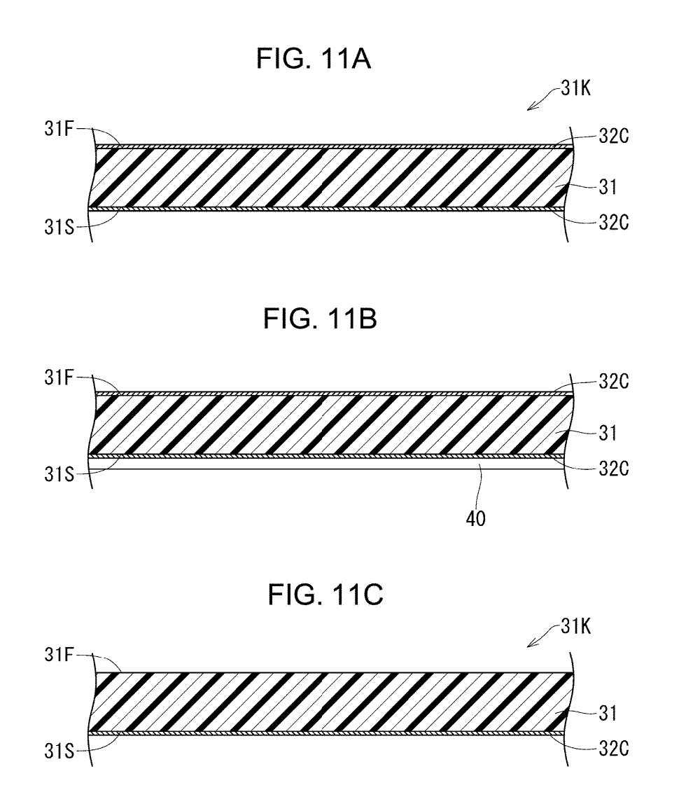

As illustrated in FIG. 11A-11C, the wiring board (10X) is different in that, when the second insulating base material 31 is prepared, the copper foil (32C) on the S surface (31S) of the second insulating base material 31 remains. Specifically, as illustrated in FIG. 11A, the copper-clad laminated plate (31K) is prepared. Next, a resist 40 is formed covering the entire copper foil (32C) on the S surface (31S) side of the copper-clad laminated plate (31K) and an etching treatment is performed (see FIG. 11B). Then, the second insulating base material 31 having the copper foil (32C) formed only on the S surface (31S) of the copper-clad laminated plate (31K) is formed (see FIG. 11C).

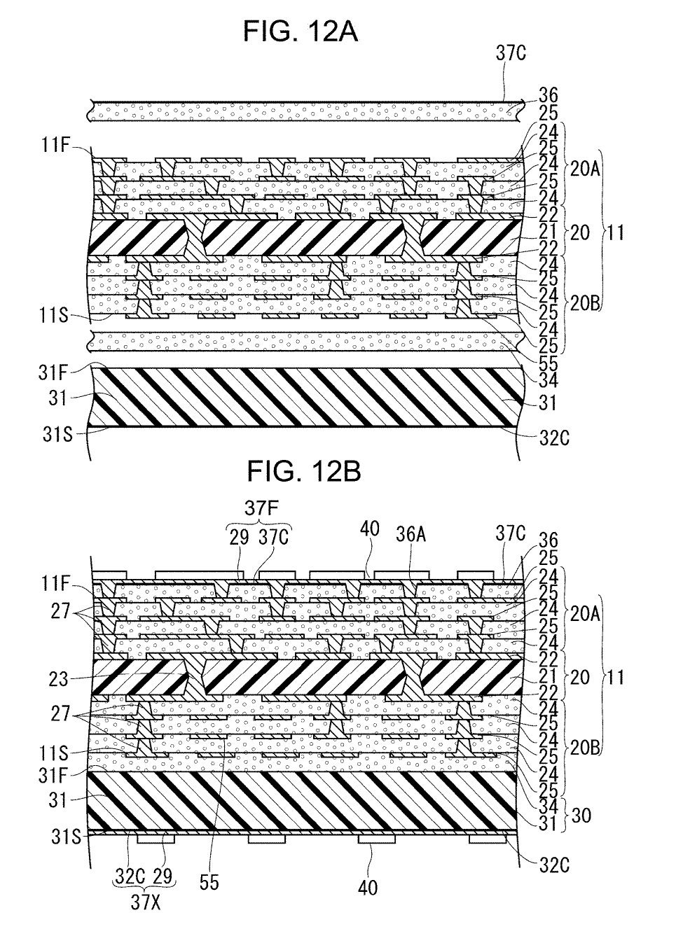

As illustrated in FIG. 12A, in an order from the F surface (11F) side of the base substrate 11, the copper foil (37C), the interlayer insulating resin layer 36, the base substrate 11, the first insulating resin layer 34, the second insulating base material 31, and the copper foil (32C) are sequentially laminated in this order, and the resulting substrate is hot-pressed. Then, the conductor layer (37S) and the conductor layer (37X) are formed by the copper foils (32C, 37C), the electroless plating film and the electrolytic plating film 29 using a subtractive method (see FIG. 12B). The metal foils respectively included in the conductor layer (37S) and the conductor layer (37X) each have a thickness of 7-10 μm.

It is thought that there is a problem that it is difficult to manufacture a multilayer wiring board having an asymmetrical structure.

A multilayer wiring board according to an embodiment of the present invention has an asymmetrical structure and can be easily manufactured.

A multilayer wiring board according to an embodiment of the present invention includes alternately laminated conductor layers and insulating layers and has an antenna part on one of a front side and a back side. The antenna part includes: a first conductor pattern; a second conductor pattern arranged on an outer layer side of the first conductor pattern; and an inter-pattern insulating layer arranged between the first conductor pattern and the second conductor pattern. The inter-pattern insulating layer includes: an insulating resin layer; and an insulating base material laminated on the insulating resin layer. A resin forming the insulating resin layer enters into gaps between portions of the first conductor pattern.

Obviously, numerous modifications and variations of the present invention are possible in light of the above teachings. It is therefore to be understood that within the scope of the appended claims, the invention may be practiced otherwise than as specifically described herein.

1. A multilayer wiring board, comprising:
a base substrate comprising a plurality of conductor layers and a plurality of insulating layers formed such that the conductor layers and the insulating layers are laminated alternately and that the plurality of conductor layers includes a first conductor pattern;
an inter-pattern insulating resin layer formed on a surface of the base substrate and comprising an insulating resin layer and an insulating base material laminated on the insulating resin layer such that resin forming the insulating resin layer is filling gaps formed between portions of the first conductor pattern; and
a second conductor pattern formed on an outer layer side of the first conductor pattern such that the inter-pattern insulating resin layer is formed between the first conductor pattern and the second conductor pattern,
wherein the base substrate, the inter-pattern insulating resin layer and the second conductor pattern form an antenna portion.

2. The multilayer wiring board according to claim 1, wherein the insulating base material has an entire surface bonded to the insulating resin layer and having a rough surface.

3. The multilayer wiring board according to claim 1, wherein the base substrate includes a core substrate such that the base substrate has the insulating layers and conductor layers alternately laminated on a front side of the core substrate and the insulating layers and conductor layers alternately laminated a back side of the core substrate, the base substrate has an outermost conductor layer having the first conductor pattern, the base substrate includes a plurality of via conductors such that the plurality of via conductors electrically connects the conductor layers through the insulating layers and that the first conductor pattern is not electrically connected to the second conductor pattern.

4. The multilayer wiring board according to claim 3, wherein the insulating base material has a thickness that is greater than a thickness of the core substrate.

5. The multilayer wiring board according to claim 1, wherein the insulating base material has a thickness that is 3 or more times a thickness of the insulating resin layer.

6. The multilayer wiring board according to claim 1, wherein the inter-pattern insulating resin layer has the insulating resin layer in a plurality such that the plurality of insulating resin layers includes a front insulating resin layer laminated on a front surface of the insulating base material and a back insulating resin layer laminated on a back surface of the insulating base material, and that the first conductor pattern is formed on the front insulating resin layer and the second conductor pattern is formed on the back insulating resin layer.

7. The multilayer wiring board according to claim 1, wherein the insulating resin layer is laminated only on one side of the insulating base material, and the second conductor pattern is formed on a surface of the insulating base material on an opposite side with respect to the insulating resin layer.

8. The multilayer wiring board according to claim 7, wherein each of the first conductor pattern and the second conductor pattern includes a metal foil formed such that the metal foil in the second conductor pattern has a thickness that is larger than a thickness of the metal foil in the first conductor pattern.

9. The multilayer wiring board according to claim 1, wherein the base substrate and the inter-pattern insulating resin layer are formed such that the insulating layers in the base substrate and the insulating resin layer in the inter-pattern insulating resin layer are formed of a same material.

10. The multilayer wiring board according to claim 9, wherein the insulating resin layer in the inter-pattern insulating resin layer includes reinforcing fibers.

11. The multilayer wiring board according to claim 1, wherein each of the conductor layers includes a metal foil, an electroless plating formed on the metal foil, and an electrolytic plating formed on the electroless plating.

12. The multilayer wiring board according to claim 2, wherein the base substrate includes a core substrate such that the base substrate has the insulating layers and conductor layers alternately laminated on a front side of the core substrate and the insulating layers and conductor layers alternately laminated a back side of the core substrate, the base substrate has an outermost conductor layer having the first conductor pattern, the base substrate includes a plurality of via conductors such that the plurality of via conductors electrically connects the conductor layers through the insulating layers and that the first conductor pattern is not electrically connected to the second conductor pattern.

13. The multilayer wiring board according to claim 12, wherein the insulating base material has a thickness that is greater than a thickness of the core substrate.

14. The multilayer wiring board according to claim 2, wherein the insulating base material has a thickness that is 3 or more times a thickness of the insulating resin layer.

15. The multilayer wiring board according to claim 3, wherein the insulating base material has a thickness that is 3 or more times a thickness of the insulating resin layer.

16. The multilayer wiring board according to claim 4, wherein the insulating base material has a thickness that is 3 or more times a thickness of the insulating resin layer.

17. The multilayer wiring board according to claim 2, wherein the inter-pattern insulating resin layer has the insulating resin layer in a plurality such that the plurality of insulating resin layers includes a front insulating resin layer laminated on a front surface of the insulating base material and a back insulating resin layer laminated on a back surface of the insulating base material, and that the first conductor pattern is formed on the front insulating resin layer and the second conductor pattern is formed on the back insulating resin layer.

18. The multilayer wiring board according to claim 3, wherein the inter-pattern insulating resin layer has the insulating resin layer in a plurality such that the plurality of insulating resin layers includes a front insulating resin layer laminated on a front surface of the insulating base material and a back insulating resin layer laminated on a back surface of the insulating base material, and that the first conductor pattern is formed on the front insulating resin layer and the second conductor pattern is formed on the back insulating resin layer.

19. The multilayer wiring board according to claim 4, wherein the inter-pattern insulating resin layer has the insulating resin layer in a plurality such that the plurality of insulating resin layers includes a front insulating resin layer laminated on a front surface of the insulating base material and a back insulating resin layer laminated on a back surface of the insulating base material, and that the first conductor pattern is formed on the front insulating resin layer and the second conductor pattern is formed on the back insulating resin layer.

20. The multilayer wiring board according to claim 1, wherein the second conductor pattern is formed on the outer layer side of the first conductor pattern such that the second conductor pattern is positioned adjacent to the first conductor pattern.
